(19) United States
(12) Patent Application Publication
(10) Pub. No.: US 2007/0272934 A1
(43) Pub. Date: Nov. 29, 2007

(54) LED device with improved life performance

(76) Inventor: Kee Yean Ng, Penang (MY)

Correspondence Address: Kathy Manke;Avago Technologies Limited, 4380 Ziegler Road, Fort Collins, CO, 80525, US

(21) Appl. No.: 11/439,028

(22) Filed: May 23, 2006

(51) Int. Cl. H01L 33/00

(52) U.S. Cl. 257/95

(57) ABSTRACT

A light-emitting diode with an improved service life is provided. The diode is formed from a transparent outer shell that contains a heat-resistant encapsulant at least partially surrounding a light-emitting diode clip. The first encapsulant is compressed between the outer shell and a second encapsulant when it is sealed into the outer shell by the second encapsulant.

### CROSS-REFERENCE TO RELATED APPLICATIONS

Not applicable.

### TECHNICAL FIELD

The present invention relates to light-emitting diodes, (LEDs) with improved performance life. More specifically the present invention describes an LED which is at least partially encapsulated with a pre-compressed encapsulant placed within an outer shell and held in place by a second encapsulant.

### BACKGROUND OF THE INVENTION

Most existing LED designs encapsulate an LED within a clear resin which are able to transmit the light produced by the LED. An example of this type of LED is shown in FIG. 1. LED device 10 is formed from LED 11 and terminals 12 which are surrounded by a clear epoxy resin 13. The resin is applied in a liquid, or flowable form and allowed to harden by curing to form the hard shell. Epoxy resins are most often used because of their and good physical properties when cured. Use of epoxy resins also allows for the LED to be formed into a number of shapes, usually a dome-like structure.

The major disadvantage with the resins typically used to make LEDs is their poor heat resistance. Repeated exposure to elevated temperatures during the life of the LED causes the encapsulating material to degrade significantly reducing the usable life of the LED.

One solution is the use of silicone based resins as encapsulants. While these materials have superior heat resistance, they generally do not have the hardness of the traditional epoxy based encapsulants. Because of the lower hardness, silicone based resins generally can not be readily shaped into standard LED shapes, such as the dome like structure shown in FIG. 1. In addition the harder the silicone resin, the more prone the resin is to exhibiting cracking over time. Therefore the use of hard silicone resins as a substitute for epoxy resins is not an acceptable alternative.

What is needed is an LED design that benefits from the thermal properties of silicone or similar materials, while maintaining the hardness and durability of epoxy resin based designs.

### BRIEF SUMMARY OF THE INVENTION

In an embodiment of the present invention a light-emitting diode with an enhanced useful life based on improved thermal performance is described. An LED is at least partially encapsulated within a pre-compressed, heat resistant encapsulant which has been placed within an outer shell. The first encapsulant is sealed into the outer shell by a layer of a second encapsulant.

In another embodiment of the present invention a method for manufacturing an LED is described. The method includes placing a pre-compressed encapsulant within an outer shell, wherein an LED is at least partially encapsulated in the pre-compressed encapsulant, and sealing the pre-compressed encapsulant within the outer shell using a second encapsulant material.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 is a cross section of a prior art LED design;

FIG. 2 is a cross section of an embodiment of an LED device design in accordance with the concepts of the present invention;

FIG. 3 is a cross section on an alternate embodiment of an LED design in accordance with the concepts of the present invention; and

FIG. 4 is a flow chart illustrating an embodiment of a method of making an LED device in accordance with the concepts of the present invention.

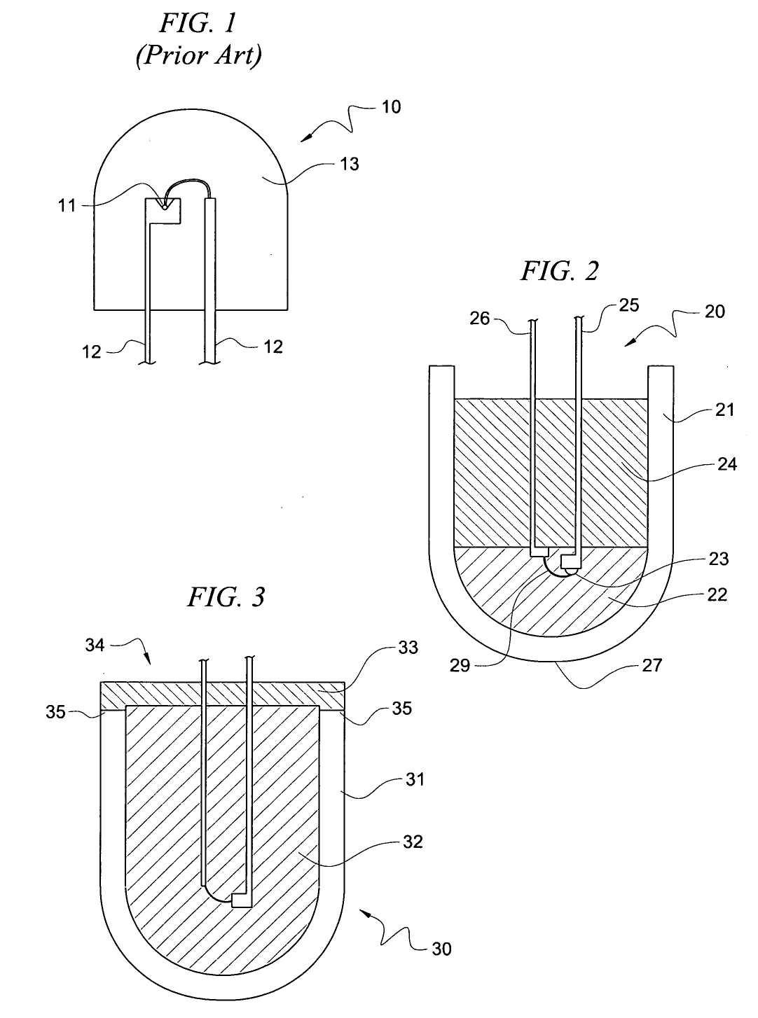

### DETAILED DESCRIPTION OF THE INVENTION

In accordance with the concepts set forth herein, a light-emitting diode (LED) device which has improved thermal properties over traditional LED designs is described. Embodiments of the present invention include a pre-compressed encapsulant with improved thermal properties, which at least partially surrounds or encapsulates a light-emitting diode. An hard outer shell is used in association with the pre-compressed encapsulant to enclose the compressible encapsulant and to ensure that the finished LED has the desired shape. A second encapsulant can also be used to seal the first encapsulant into the shell.

Referring to FIG. 2, a preferred embodiment of an LED 20 according to the concepts described herein is shown. LED 20 includes an outer shell 21, which is formed from a transparent material such as a non-thermally cured epoxy, a plastic material, or any other material with the desired transparency and rigidity. A first encapsulant 22 is placed in outer shell 21 in either a solid or liquid form and at least partially surrounds or encapsulates LED chip 23. In embodiments of the present invention, the first encapsulant is heat resistant and compressible, and may be a silicone based polymer such as a polysiloxane, or other any other material with appropriate thermal properties which is also compressible and capable of transmitting light of a wavelength appropriate to LED chip 23.

LED chip 23 is placed in first encapsulant 22 and outer shell 21 to allow light produces by LED chip 23 to pass through first encapsulant 22 and outer shell 21. In the embodiment shown in FIG. 2, a second encapsulant 24 is placed in outer shell 21, thereby sealing the first encapsulant 22 into the outer shell 21. LED chip 23 is directly connected to lead 25 and is electrically connected to lead 26 by a wire 29.

In certain embodiments, second encapsulant 24 is introduced into outer shell 21 in such a manner to allow it to pre-compresses first encapsulant 22 against the outer shell 21. This can be accomplished by first introducing the first encapsulant 22 into the outer shell 21 and curing the encapsulant 22. Outer shell 21 and first encapsulant 22 may then cooled to a temperature that results in the contraction of the first encapsulant 22. Once first encapsulant 22 has contracted, second encapsulant 24 is introduced into outer shell 21 so as to seal first encapsulant 22 into the outer shell 21. When the temperature of the LED is raised, for example to room temperature or above, first encapsulant 22 attempts to expand, pushing against outer shell 21 and second encapsulant 24. The first and second encapsulants should completely fill at least the closed portion of outer shell 21 to prevent air pockets from forming which might reduce the desired compression of first encapsulant 21. Because outer shell 21 and second encapsulant 24 are rigid and sufficiently bonded to each other, the first encapsulant becomes compressed.

The compression of the first encapsulant 22 described above is use to overcome traditional disadvantages of compressible materials such as silicone which can tend to delaminate from the walls of outer shell 21 during temperature excursions. By pre-compressing first encapsulant 22 in outer shell 21 the delamination effects can be reduced or eliminated.

In preferred embodiments, second encapsulant 24 is formed from a different material from first encapsulant 22, which can be a curable resin or other material which has the properties described herein. In the case of resin materials, the resin when cured, generally produces a material which is harder than the first encapsulant and preferably rigid in order to maintain the compression of first encapsulant 22. In certain embodiments, the second encapsulant may be an epoxy.

As described, preferred embodiments of outer shell 21 are formed from a material which is transparent at least to the wavelengths of light produced by LED chip 23, and possesses sufficient rigidity to retain its shape even when subject to the forces placed on it by compressed first encapsulant 22. Outer shell 21 can be of desired shape, color or configuration as required to provide an LED with the desired properties. In certain embodiments, outer shell 21 can be a light shaping structure such as dome 27 is shown in FIGS. 2 and 3. Additionally, embodiments of the outer shell may be formed from a semicrystalline engineering polymer

As discussed above with reference to FIG. 2, second encapsulant 24 forms a layer across the surface of the first encapsulant 12. Also as shown in FIG. 2, second encapsulant 24 can be placed within outer shell 21 to substantially fill the portion of outer shell 21 not filled by first encapsulant 22, thereby sealing first encapsulant 22 within outer shell 21.

In alternate embodiments, first encapsulant 22 may be sealed in outer shell 21 by other LED configurations, such as by LED 30 shown in FIG. 3. In the embodiment of LED 30 shown in FIG. 3, first encapsulant 32 completely fills outer shell 31. Second encapsulant 33 is placed across open end 34 of outer shell 31, such that second encapsulant completely, or substantial contacts the surface of first encapsulant 22 at open end 34 and overlaps onto rim 35 of outer shell 31. In certain embodiments of the LED described herein, the bond between the second encapsulant and the outer shell should be sufficient to withstand the pressure placed against the second encapsulant by the compressed first encapsulant in order to maintain the desired compression of the first encapsulant.

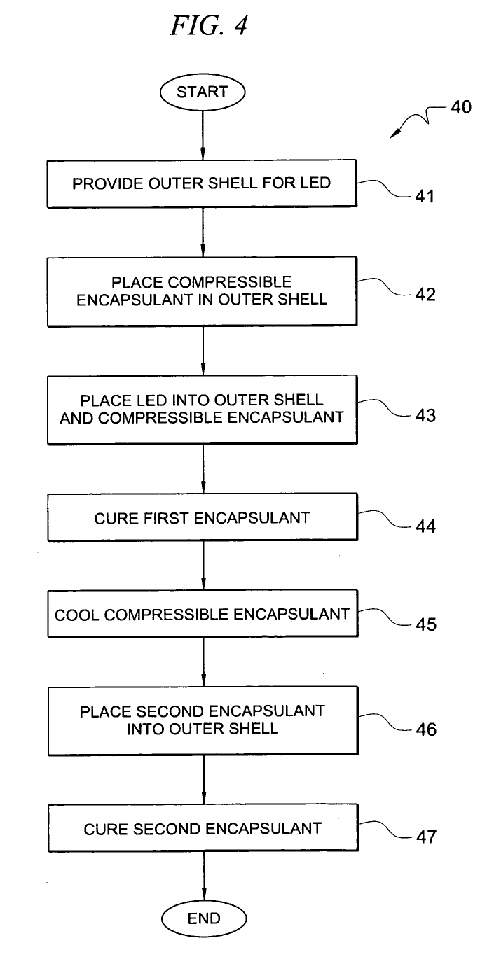

Referring now to FIG. 4, an embodiment of method for making LEDs according to the concepts described herein is shown. Method 40 begins with process 41 where an outer shell is provided having the desired properties. Next, in process 42, a compressible encapsulant is placed with the outer shell, at least partially filling the outer shell. A light-emitting diode chip is then placed into the pre-compressed encapsulant such that the chip is at least partially encapsulated by the compressible encapsulant as shown by process 43.

The pre-compressed encapsulant is then cured in process 44. In process 45, the outer shell containing the pre-compressed encapsulant and the LED chip is then cooled such that the cured first encapsulant contracts. This temperature is generally below room temperature. Once the first encapsulant has contracted, a second encapsulant is then layered on top of the first encapsulant such that the second encapsulant as shown by process 46. When cured, as shown by process 47, the second encapsulant seals the first encapsulant within the outer shell. In certain embodiments, the curing of the second encapsulant can be done by non-thermal methods, which do not raise the temperature of the first encapsulant. After curing the second encapsulant the finished LED can be allowed to warm to room temperature resulting in the first encapsulant expanding, or pressing against the outer shell and the second encapsulant

While the embodiment of method 40 shown in FIG. 4 shows placing the encapsulant in the outer shell and then placing the LED at least partially within the compressible encapsulant, the order of placement of the LED and the compressible encapsulant, or even the second encapsulant, is not important. Any method that results in the proper structure of LED and the compressible encapsulant and the second encapsulant is well within the scope of the concepts described herein. This may also include placing LED already preformed with a compressible encapsulant within the outer shell.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A light-emitting diode comprising:
an outer shell;
a first encapsulant disposed within said outer shell;
a light-emitting diode chip at least partially surrounded by said first encapsulant; and
a second encapsulant sealing said first encapsulant within said outer shell.

2. The light-emitting diode of claim 1 wherein said first encapsulant is compressed against said outer shell by said second encapsulant.

3. The light-emitting diode of claim 1 where in said first encapsulant is heat resistant.

4. The light-emitting diode of claim 1 wherein said first encapsulant is a silicone containing polymer.

5. The light-emitting diode of claim 4 wherein the silicone containing polymer comprises polysiloxane.

6. The light emitting diode of claim 1 wherein the outer shell is a semicrystalline engineering polymer.

7. The light-emitting diode of claim 1 wherein said second encapsulant is disposed in said outer shell to seal said first encapsulant.

8. The light-emitting diode of claim 1 wherein said second encapsulant covers an open end of said outer shell to seal said first encapsulant.

9. A light-emitting diode comprising:
an outer shell;
a light-emitting diode (LED) chip disposed within the outer shell;
a first encapsulant at least partially surrounding said LED chip, said first encapsulant filling at least a portion of said outer shell; and
a second encapsulant at least partially filling the remaining portion of said outer shell such that the second encapsulant seals said first encapsulant within the outer shell.

10. The light-emitting diode of claim 9 wherein said first encapsulant is held compressed within said outer shell by said second encapsulant.

11. The light-emitting diode of claim 9 wherein said outer shell is a semicrystalline engineering resin.

12. The light-emitting diode of claim 10 wherein said first encapsulant is cooled before the second encapsulant is added.

13. The light-emitting diode of claim 9 wherein said first encapsulant is a silicone containing polymer.

14. The light-emitting diode of claim 9 wherein said first encapsulant is polysiloxane.

15. The light-emitting diode of claim 9 further comprising one or more leads electronically connected to said chip.

16. The light-emitting diode of claim 9 wherein said second encapsulant is an epoxy.

17. A method for manufacturing a light-emitting diode comprising;
providing an outer shell;
placing a light-emitting diode chip and a first encapsulant within said outer shell wherein said first encapsulant, encapsulates at least a portion of said chip;
cooling said first encapsulant so that said first encapsulant contracts; and
adding a second encapsulant to said outer shell to seal said first encapsulant within said outer shell.

18. The method of claim 17 wherein said first encapsulant is compressed between said second encapsulant and said outer shell as said first encapsulant warms.

19. The method of claim 17 wherein said first encapsulant comprises a silicone containing polymer.

20. The method of claim 17 wherein said second encapsulant comprises epoxy resin.
